(19) United States
(12) Patent Application Publication
(10) Pub. No.: US 2018/0315915 A1
(43) Pub. Date: Nov. 1, 2018

(54) THERMOELECTRIC MODULE AND DEVICE, IN PARTICULAR FOR GENERATING AN ELECTRIC CURRENT IN A MOTOR VEHICLE

(71) Applicant: Valeo Systemes Thermiques, Le Mesnil Saint Denis (FR)

(72) Inventors: Kamel Azzouz, Le Mesnil Saint Denis (FR); Patrick Boisselle, Le Mesnil Saint Denis (FR); Cedric De Vaulx, Le Mesnil Saint Denis (FR); Véronique Monnet, Le Mesnil Saint Denis (FR); Ambroise Servantie, Le Mesnil Saint Denis (FR)

(73) Assignee: Valeo Systemes Thermiques, Le Mesnil Saint Denis (FR)

(21) Appl. No.: 15/760,023

(22) PCT Filed: Sep. 9, 2016
(86) PCT No.: PCT/FR2016/052259

§ 371 Date: Jul. 18, 2018

(30) Foreign Application Priority Data
Sep. 15, 2015 (FR) 1558643

(51) Int. Cl. H01L 35/30; H01L 35/32

(52) U.S. Cl. CPC H01L 35/30; H01L 35/32

(57) ABSTRACT

The present invention concerns a thermoelectric module comprising at least one plurality of cylindrical thermoelectric elements (1n,1p) comprising a circular central opening receiving a central tube (5), a first fluid being intended to circulate through the central tube (5) and a second fluid being intended to circulate around the exterior periphery, a so-called interior tubular electrode (9) fastened to an interior face of each thermoelectric element (1n,1p), a so-called exterior tubular electrode (7) fastened to the exterior face of each thermoelectric element (1n,1p), and fins (2) extending from an exterior face of said thermoelectric element (1n,1p) and perpendicularly to the axis of its central opening, said central tube (5) being made of aluminum and having a wall thickness between 150 and 500 μm inclusive.

The present invention relates to a thermoelectric module and a thermoelectric device, in particular intended to generate an electric current in a motor vehicle.

In the automotive field thermoelectric devices, also termed thermoelectric generators (TEG), have already been proposed using so-called thermoelectric elements enabling generation of an electric current in the presence of a temperature gradient between two of their opposite faces by the phenomenon known as the Seebeck effect. These devices comprise a stack of first tubes, intended for the circulation of the exhaust gases from an engine, and second tubes, intended for the circulation of a heat transfer fluid from a cooling circuit. The thermoelectric elements are sandwiched between the tubes so as to be subjected to a temperature gradient resulting from the temperature difference between the hot exhaust gases and the cold cooling fluid.

Such devices are of particular interest because they enable production of electricity by conversion of heat coming from the exhaust gases of the engine. They therefore offer the possibility of reducing the fuel consumption of the vehicle through being substituted, at least in part, for the alternator usually provided therein to generate electricity by means of a belt driven by the crankshaft of the engine.

There have already been developed by the applicant thermoelectric elements of annular shape in which the temperature gradient enabling generation of the electric current is imposed between two of their opposite cylindrical faces, the hot fluid and the cold fluid circulating coaxially, one inside the ring and the other outside it. This type of thermoelectric element is difficult to integrate and this leads to the use of a large quantity of material adding to the unit cost and increasing the thermal inertia of the device.

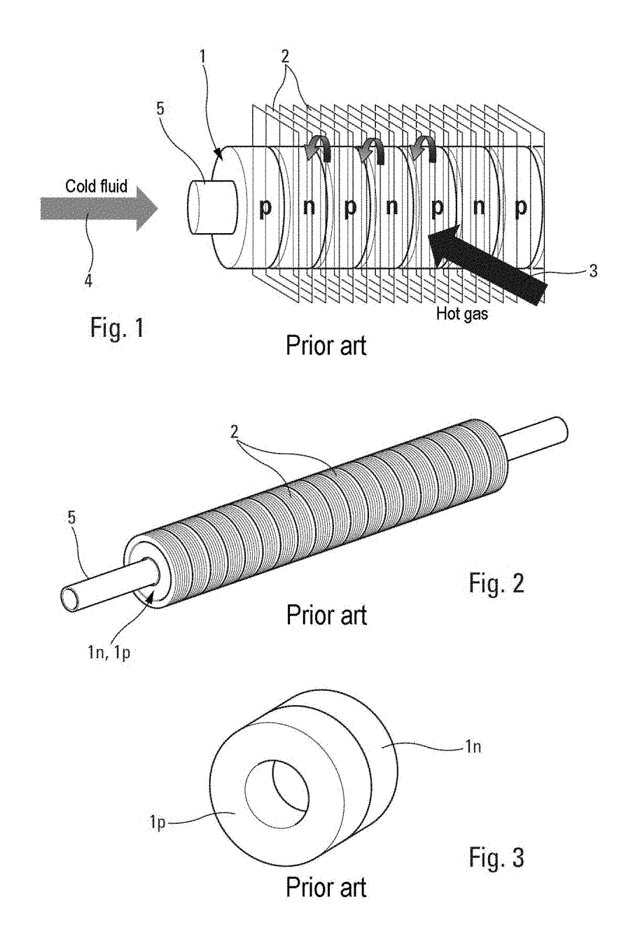

To remedy these disadvantages, the applicant has developed a thermoelectric module including thermoelectric elements of annular shape in which the first fluid and the second fluid circulate transversely relative to one another. A thermoelectric module of this kind is represented in FIGS. 1 to 3 and includes a plurality of thermoelectric elements 1 of annular shape disposed coaxially and longitudinally in line with one another, for example with an alternation of N-type thermoelectric elements and P-type thermoelectric elements. Each thermoelectric element 1 includes fins 2 extending transversely and radially from the exterior periphery. These fins 2 make it possible to favor the exchange of heat with the hot exhaust gases 3 that circulate across aid fins 2, a cold fluid 4 circulating at the center of the thermoelectric elements 1 through a tube 5, and to extract the maximum heat from the exhaust gases to transfer it to the thermoelectric materials.

To channel the hot gases across the fins 2, there is usually employed a cylindrical enclosure capping the fins 2 of the thermoelectric elements 1 that are assembled in the form of a cylindrical pencil, the thermoelectric elements pencil 1 being inserted in the cylindrical enclosure the inside diameter of which is adjusted to suit the outside diameter of the fins 2 which then have a circular shape. In order to produce a thermoelectric generator, a plurality of pencils can be assembled together, the number of pencils depending on the required electrical power.

The various elements of these thermoelectric modules are generally assembled by brazing and this type of assembly by brazing is generally not the optimum. Actually, this type of assembly necessitates compatibility of the materials to be assembled in order to accommodate the differential expansion stresses of the various elements and problems with brazing the chosen alloy or alloys.

The invention proposes to improve on the situation to optimize assembly and to that end concerns a thermoelectric module comprising at least one plurality of cylindrical thermoelectric elements comprising a circular central opening receiving a central tube, said thermoelectric elements being adapted to generate an electric current because of a temperature gradient exerted between a first, so-called exterior face defined by an exterior periphery surface and a second, so-called interior face defined by an interior periphery surface, a first fluid being intended to circulate through the central tube and a second fluid being intended to circulate around the exterior periphery, said central tube being made of aluminum and having a wall thickness between 150 and 500 μm inclusive.

This is therefore a tube enabling mechanical assembly, that is to say by expansion of its section.

According to various embodiments of the invention, separately or in combination:
the exterior surface of the central tube includes an electrical insulation layer the thickness of which is between 25 and 150 μm inclusive,
the electrical insulation layer is made of alumina,
said module further comprising a so-called interior tubular electrode fastened to the interior face of each thermoelectric element,
the tubular interior electrode has a thickness between 80 and 300 μm inclusive,
the tubular interior electrode is made of copper,
the external surface of the tubular interior electrode includes a so-called diffusion barrier layer to prevent the diffusion of brazing elements, said diffusion barrier having a thickness between 1 and 10 μm inclusive,
the diffusion barrier layer is made of nickel,
between the interior face of the thermoelectric element and the diffusion barrier is deposited a brazed joint having a wall thickness between 5 and 100 μm inclusive,
the brazed joint is made of a metal alloy including aluminum or tin,
the interior face of the thermoelectric element includes a so-called second diffusion barrier layer having a thickness between 1 and 10 μm inclusive,
said second diffusion barrier is constituted of a plurality of layers made from metal or metal alloys and an external nickel layer in contact with the brazed joint,
each thermoelectric element has a thickness between 1 and 10 mm inclusive,
the exterior surface of each thermoelectric element includes a so-called third diffusion barrier layer having a thickness between 1 and 10 μm inclusive,
said third diffusion barrier is constituted of a plurality of layers made of metal or metal alloys and an external nickel layer,
on the external layer of the third diffusion barrier layer is deposited a second brazed joint having a thickness between 5 and 100 μm inclusive,
the second brazed joint is made of a metal alloy including aluminum or tin,
said module further comprises a so-called exterior tubular electrode fastened to the exterior face of each thermoelectric element,
the interior surface of the exterior tubular electrode includes a so-called fourth diffusion barrier layer having a thickness between 1 and 25 μm inclusive,
said fourth diffusion barrier layer is constituted of a layer of nickel,
the exterior tubular electrode has a thickness between 80 and 300 μm inclusive,
the exterior tubular electrode is made of copper,
the exterior surface of the exterior tubular electrode includes a so-called protective layer to limit oxidation of the exterior tubular electrode by the second fluid,
said protective layer is made of nickel,
said module further comprises fins extending from the exterior face of said thermoelectric element and perpendicularly to the axis of its central opening,
each fin is constituted of a circular washer and an annular flange fastened to the interior edge of said fin and extending perpendicularly to the latter.

The invention also concerns a thermoelectric device comprising a plurality of modules as described above.

Said device is advantageously configured to be positioned in a motor vehicle exhaust gas pipe so that said gases circulate between the fins, said gases defining the second fluid.

The invention will be better understood in the light of the following description which is given by way of illustration only and not to limit the invention, accompanied by the appended drawings in which:

FIG. 1 is a diagrammatic representation in perspective of a prior art thermoelectric module,

FIG. 2 is a perspective view of a prior art thermoelectric module,

FIG. 3 is a perspective view of the assembly of two thermoelectric elements of a prior art thermoelectric module,

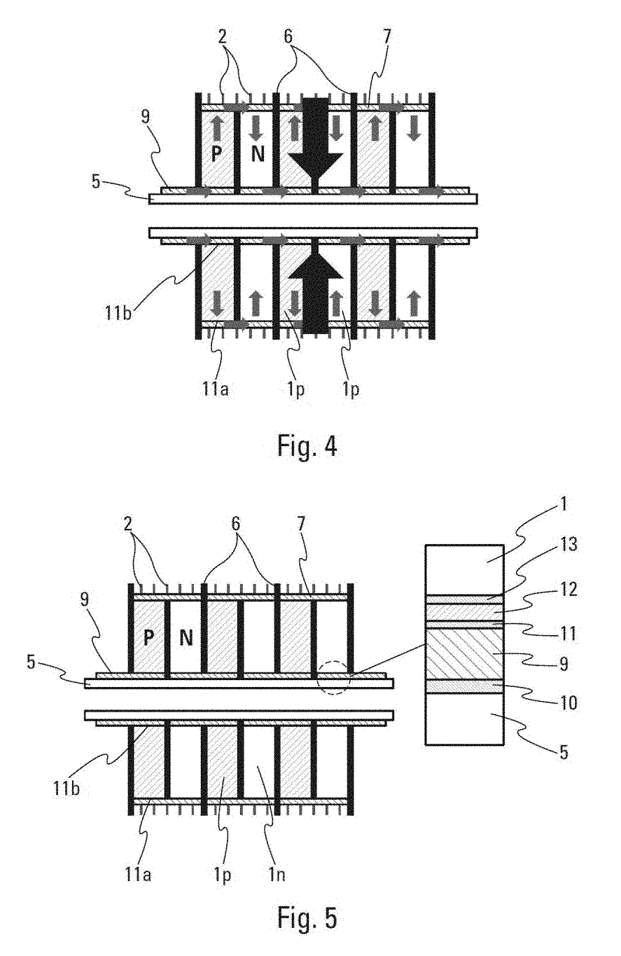

FIG. 4 is a diagrammatic representation in longitudinal section of a thermoelectric module according to the invention,

FIG. 5 is a diagrammatic representation in longitudinal section of a detail of the thermoelectric module according to the invention,

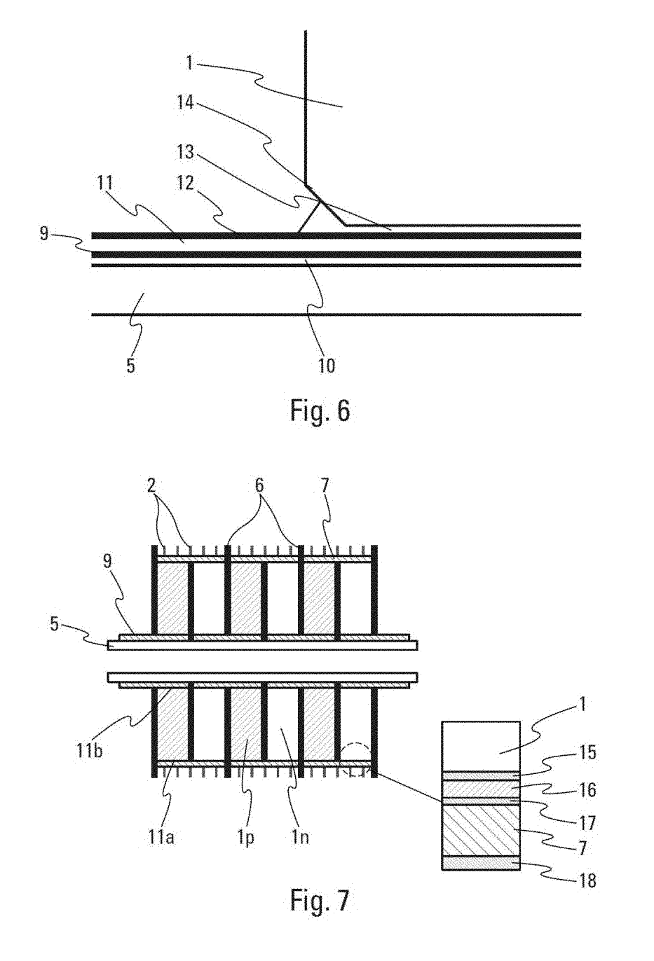

FIG. 6 is a view in longitudinal section of the assembly of a thermoelectric element onto a tube of the thermoelectric module according to the invention,

FIG. 7 is a diagrammatic representation in longitudinal section of a detail of the assembly of the fins of the thermoelectric module according to the invention,

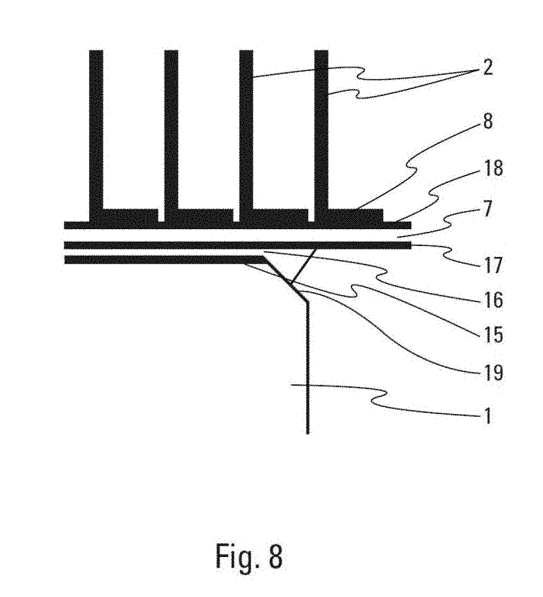

FIG. 8 is a partial view in longitudinal section of the assembly of the fins onto a thermoelectric element of the thermoelectric module according to the invention.

In the figures, identical or analogous elements carry the same references.

As shown in FIGS. 4 and 5, the invention concerns a thermoelectric module that comprises a plurality of thermoelectric elements 1n,1p of cylinder or right prism shape and including a central opening, adapted to generate an electric current because of a temperature gradient exerted between a first, so-called exterior face 11a defined by an exterior periphery surface and a second, so-called interior face 11b defined by an interior periphery surface, the heat transfer fluid from the cooling circuit being intended to circulate through the central opening in a tube 5 and the hot exhaust gases being intended to circulate around the exterior periphery.

It will be noted that the exterior face 11a and the interior face 11b of the thermoelectric elements 1 are for example circular. However, more generally, any section of rounded shape, such as an oval shape for example, and/or a polygonal shape, is possible.

Elements of this kind operate in accordance with the Seebeck effect, enabling an electric current to be created in a load connected between the interior face 11b and the exterior face 11a of the thermoelectric elements 1n,1p subjected to the temperature gradient.

The thermoelectric elements could be, for a first part, elements 1p of a first, so-called P type, enabling an electric potential difference to be established in a so-called positive direction when they are subjected to a given temperature gradient, and, for the other part, elements 1n of a second so-called N type enabling the creation of an electric potential difference in an opposite, so-called negative direction when they are subjected to the same temperature gradient.

Said thermoelectric elements 1 represented are constituted of a one-piece ring. They could however be formed from a plurality of parts each forming an angular portion of the ring.

The exterior surface 11a has, for example, a radius between 1.5 and 4 times inclusive the radius of the interior surface 11b. This could be a radius equal to approximately twice that of the interior surface 11b.

Said thermoelectric element 1 has, for example, two opposite parallel plane faces. In other words, the ring constituting the thermoelectric element 1 is of rectangular annular shape.

Said thermoelectric elements 1p, 1n are disposed, for example, longitudinally in line with one another, in particular in a coaxial manner, and the type P thermoelectric elements alternate with the type N thermoelectric elements in a direction D. They are in particular of identical shape and size. They could however have a thickness, that is to say a dimension between their two plane faces, different from one type to another, in particular as a function of their electrical conductivity.

Said thermoelectric elements 1p, 1n are, for example, grouped in pairs, each pair being formed of one of said type P thermoelectric elements and one of said type N thermoelectric elements, and said module is configured to enable circulation of current between the first surfaces of the thermoelectric elements 1 of the same pair and circulation of current between the second surfaces of each of the thermoelectric elements 1 of said same pair and the adjacent thermoelectric element 1 of the adjacent pair. This ensures that the electric current flows in series between the thermoelectric elements 1p, 1n disposed one alongside the other in the direction D.

Said module further comprises electrical insulation means 6 disposed between two facing faces of adjacent thermoelectric elements 1p, 1n in the longitudinal direction D in which the tube 5 extends.

Referring to FIGS. 4 and 5, said module also comprises first electrical connection means 7 connecting the exterior periphery surfaces 11a of said two adjacent thermoelectric elements 1n and 1p and of different types. Said first electrical connection means 7 consist in a tubular, so-called exterior electrode fastened to the exterior face of each thermoelectric element 1n, 1p, made of copper enabling two contiguous thermoelectric elements 1n, 1p to be brazed.

Said module advantageously comprises secondary exchange surfaces, in particular fins 2, for exchanges with the exhaust gases. This increases the area of exchange between the thermoelectric elements 1 and the exhaust gases. Said fins 2 are disposed transversely, for example, in particular radially relative to said thermoelectric elements 1. Here they are positioned parallel to one another with a gap enabling good exchange of heat with the second fluid whilst limiting head losses.

Said fins 2 could comprise a catalytic coating to provide catalytic conversion of toxic components of the second fluid. In the case of exhaust gas, said module could therefore equip a catalytic converter in addition to instead of the catalysis components conventionally used in such equipments.

Said fins 2 are constituted of circular washers comprising a flange 8 fastened to the interior edge of said washers, said flange 8 having a width greater than the thickness of said fin 2.

In this embodiment, the flanges 8 of the fins 2 extend on only one side of said fins 2. However, it is obvious that the flanges 8 could extend on either side of the fins 2 without this departing from the scope of the invention.

Said fins 2 are fixed to the exterior electrode 6 by crimping as described in detail hereinafter.

In this embodiment, the fins 2 are plane and extend parallel to one another; however, in order to improve the performance of the fins 2, that is to say the convection between the hot exhaust gases and the fins 2, said fins 2 could be corrugated.

In an ancillary manners, said fins 2 could have a rough surface state, produced by sandblasting for example, in order also to improve the efficacy of said fins.

Moreover, the module also comprises second electrical connection means 9 establishing an electrical connection between the interior periphery surfaces of two adjacent thermoelectric elements 1 of different types not connected by said electrical connection means 8.

In other words, said first electrical connection means 7 and said second electrical connection means 9 connect said thermoelectric elements 1 two by two so as to establish a series electrical circuit between said thermoelectric elements 1 of the module.

Referring to FIGS. 5 and 6, in order to optimize assembly by brazing of the thermoelectric elements 1 onto the central tube 5, said central tube 5 is made of aluminum and has a wall thickness between 150 and 500 μm inclusive. This thickness of the central tube 5 imparts to said tube 5 a sufficient resistance to expansion when crimping the thermoelectric elements onto the central tube 5, the latter being crimped to the tube by force-fitting said thermoelectric elements onto the tube 5 and then by expanding said tube 5 by hydroforming. Moreover, this thickness produces a sufficiently low thermal resistance between the heat exchange fluid of the cooling circuit circulating in the central tube 5 and the thermoelectric elements 1.

The exterior surface of the central tube 5 includes an electrical insulation layer 10 the thickness of which is between 25 and 150 μm inclusive. This electrical insulation layer 10 is made of alumina. This layer enables prevention of a short circuit between all the pairs of thermoelectric elements 1n,1p. Its thickness enables insulation of the aluminum of the central tube 5 from the tubular interior electrode 9 whilst not constituting too high a thermal resistance. Moreover, the tubular interior electrode 9 is made of copper with a thickness between 80 and 300 μm inclusive. The external surface of the tubular interior electrode 9 includes a so-called diffusion barrier layer 11 to prevent diffusion of the brazing elements, said diffusion barrier 11 having a thickness between 1 and 10 μm inclusive. This diffusion barrier 11 is preferably made of nickel. It enables prevention of diffusion of the brazing elements to the adjoining layer and vice versa. Moreover, between the interior face of the thermoelectric element 1 and the diffusion barrier layer 11, a brazed joint 12 having a thickness between 5 and 100 μm inclusive is deposited, said brazed joint 12 being made of a metal alloy including aluminum or tin. The interior face of the thermoelectric element 1 advantageously includes a so-called second diffusion barrier layer 13 having a thickness between 1 and 10 μm inclusive. This second diffusion barrier 13 is constituted of a plurality of layers made of metal or metal alloys and an external nickel layer in contact with the brazed joint 12. Each thermoelectric element 1 has a thickness between 1 and 10 mm inclusive and is preferably made of magnesium silicide or manganese silicide. It will be noted that the edge of the interior face of the thermoelectric elements 1 are beveled. These bevels 14 enable prevent of flash on the brazed joint 12.

Moreover, referring to FIGS. 7 and 8, the exterior surface of each thermoelectric element 1 includes a so-called third diffusion barrier layer 15 having a thickness between 1 and 10 μm inclusive. This third diffusion barrier 15 is constituted of a plurality of layers made of metal or metal alloys and an external nickel layer. Onto the external layer of the third diffusion barrier 16 is deposited a second brazed joint 16 having a thickness between 5 and 100 μm inclusive. Said second brazed joint 16 is made of a metal alloy including aluminum or tin. Moreover, the interior surface of the tubular exterior electrode 10 includes a so-called fourth diffusion barrier layer 17 having a thickness between 1 and 25 μm inclusive. This fourth diffusion barrier 17, which enables prevention of diffusion of the brazing elements to the adjoining layer and vice versa, is preferably constituted of a layer of nickel. Said tubular exterior electrode 10 has a thickness between 80 and 300 μm inclusive and is made of copper. Moreover, the exterior surface of the tubular exterior electrode 7 includes a so-called protective layer 18 to limit oxidation of the tubular exterior electrode 10 by the exhaust gases. This protective layer 18 is also made of nickel. The fins 2, preferably made of stainless steel, are crimped onto the protective layer 18 and preferably have a thickness between 25 and 150 m inclusive. Said fins 2 could alternatively be made of aluminum.

It will be noted that the edges of the exterior face of the thermoelectric elements 1 are chamfered. These chamfers 19 enable prevention of flash on the brazed joint 16.

It will be seen that these various layers described in detail above enable optimized assembly and robustness of the thermoelectric module.

It is understood that the present invention is in no way limited to the embodiments described above and that modifications can be made thereto without departing from the scope of the appended claims.

1. A thermoelectric module comprising:
at least one plurality of cylindrical thermoelectric elements comprising a circular central opening receiving a central tube,
said thermoelectric elements being adapted to generate an electric current because of a temperature gradient exerted between a first exterior face defined by an exterior periphery surface and a second, interior face defined by an interior periphery surface,
a first fluid for circulating through the central tube and a second fluid for circulating around the exterior periphery,
said central tube being made of aluminum and having a wall thickness between 150 and 500 μm inclusive.

2. The module as claimed in claim 1, wherein the exterior surface of the central tube includes an electrical insulation layer the thickness of which is between 25 and 150 μm inclusive.

3. The module as claimed in claim 2, wherein the electrical insulation layer is made of alumina.

4. The module as claimed in claim 1, further comprising a so-called interior tubular electrode fastened to the interior face of each thermoelectric element.

5. The module as claimed in claim 4, wherein the tubular interior electrode has a thickness between 80 and 300 μm inclusive and said tubular interior electrode is made of copper.

6. The module as claimed in claim 4, wherein the external surface of the tubular interior electrode includes a diffusion barrier layer to prevent the diffusion of brazing elements, said diffusion barrier having a thickness between 1 and 10 μm inclusive.

7. The module as claimed in claim 6, wherein the diffusion barrier is made of nickel.

8. The module as claimed in claim 6, wherein, between the interior face of the thermoelectric element and the diffusion barrier is deposited a brazed joint having a wall thickness between 5 and 100 μm inclusive.

9. The module as claimed in claim 8, wherein the brazed joint is made of a metal alloy including aluminum or tin.

10. The module as claimed in claim 8, wherein the interior face of the thermoelectric element includes a second diffusion barrier layer having a thickness between 1 and 10 μm inclusive.

11. The module as claimed in claim 10, wherein said second diffusion barrier is constituted of a plurality of layers made from metal or metal alloys and an external nickel layer in contact with the brazed joint.

12. The module as claimed in claim 1, wherein each thermoelectric element has a thickness between 1 and 10 mm inclusive.

13. The module as claimed in claim 1, wherein the exterior surface of each thermoelectric element includes a third diffusion barrier layer having a thickness between 1 and 10 μm inclusive.

14. The module as claimed in claim 13, wherein said third diffusion barrier is constituted of a plurality of layers made of metal or metal alloys and an external nickel layer.

15. The module as claimed in claim 13, wherein, on the external layer of the third diffusion barrier layer, is deposited a second brazed joint having a thickness between 5 and 100 μm inclusive.

16. The module as claimed in claim 15, wherein the second brazed joint is made of a metal alloy including aluminum or tin.

17. The module as claimed in claim 1, further comprising a exterior tubular electrode fastened to the exterior face of each thermoelectric element.

18. The module as claimed in claim 17, wherein the interior surface of the exterior tubular electrode includes a fourth diffusion barrier layer having a thickness between 1 and 25 μm inclusive.

19. The module as claimed in claim 18, wherein said fourth diffusion barrier layer is constituted of a layer of nickel.

20. The module as claimed in claim 17, wherein the exterior tubular electrode has a thickness between 80 and 300 μm inclusive and is made of copper.

21. The module as claimed in claim 17, wherein the exterior surface of the exterior tubular electrode includes a protective layer to limit oxidation of the exterior tubular electrode by the second fluid.

22. The module as claimed in claim 21, wherein said protective layer is made of nickel.

23. The module as claimed in claim 1, further comprising fins extending from the exterior face of said thermoelectric element and perpendicularly to the axis of its central opening.

24. The module as claimed in claim 23, wherein each fin is constituted of a circular washer and an annular flange fastened to the interior edge of said fin and extending perpendicularly to the latter.

25. A thermoelectric device comprising at least one module as claimed in claim 1.

26. The thermoelectric device as claimed in claim 25, configured to be positioned in a motor vehicle exhaust gas pipe so that said gases circulate in the enclosure, said gases defining the second fluid.
